(19) United States
(12) Patent Application Publication
(10) Pub. No.: US 2004/0137697 A1
(43) Pub. Date: Jul. 15, 2004

(54) Method and apparatus for separating composite substrate

(76) Inventor: Shinichi Tomita, Saga (JP)

Correspondence Address: KANESAKA & TAKEUCHI, 1423 Powhatan Street, Alexandria, VA, 22314, US

(21) Appl. No.: 10/339,570

(22) Filed: Jan. 10, 2003

(51) Int. Cl. H01L 21/30; H01L 21/46; H01L 21/301

(52) U.S. Cl. 438/455; 438/460

(57) ABSTRACT

A method and an apparatus for separating a composite substrate 1 by which the composite substrate 1 is warped to cause a crack and grow it in a separation region 6, a silicon substrate 2 constituting the composite substrate 1 is separated along the separation region 6, and the silicon substrate 2 is separated from the composite substrate 1 with ease.

### BACKGROUND OF THE INVENTION

1. Field of the Invention

The present invention relates to a separation method and a separation apparatus for separating a composite substrate such as an SOI substrate.

2. Description of the Related Art

Conventionally, there are a bonding technology and a SIM0X process for production of SOI substrates.

But, the bonding technology had a disadvantage that a uniform and thin thickness was difficult to obtain by polishing.

The SIM0X process requires to inject 10¹⁸ ions/cm² or more of oxygen ions in order to form an SiO₂ layer and takes a long injection time. Therefore, it has problems that its productivity is low, and wafers cost high.

In recent years, there are proposed processes disclosed in U.S. Pat. No. 5,374,564, U.S. Pat. No. 6,020,252, and the like as technologies of separation at a position different from the bonded region.

As their improved technologies, there are processes disclosed in U.S. Pat. No. 6,013,563 (a technology by which particles are introduced to a selected depth, and energy is supplied to make separation), Japanese Patent No. 2877800 (a technology by which a fluid is sprayed to make separation), and the like.

The inventor had previously proposed a technology to separate respective wafers at the bonded portion when voids (bubbles) are generated in the bonded portion of bonded composite wafers (Japanese Patent Laid-Open Publication No. Hei 7-240355).

And, the inventor proposes a method and an apparatus for separating a composite substrate, which easily separate the substrate at a portion different from the bonded portion by utilizing the above technology.

Specifically, the present invention proposes a method and an apparatus which can separate a bonded (composite) substrate, which includes a separation region, along a separation region different from the bonded portion and also can separate along the bonded portion in order to reuse a substrate having voids in the bonded portion.

### SUMMARY OF THE INVENTION

The invention described in claim 1 of the present application is a method for separating a composite substrate which is formed by bonding a plurality of substrates, wherein the composite substrate is separated by warping.

According to the above configuration, the substrate can be separated by warping the composite substrate.

The invention described in claim 2 of the application is a method for separating a composite material, wherein an impulse is applied to edge of the composite substrate while keeping it in a warped state.

The composite substrate is, for example a bonded wafer which is formed by bonding a plurality of wafers, such as silicon wafers, quarts substrates, or the like, and the substrate and each substrate refer to a single substrate.

According to the above configuration, each substrate can be separated by applying the impulse to initiate separation if the separation does not propagate by warping the composite substrate in an elastic deformation region.

The invention described in claim 3 of the application is a method for separating a composite substrate, wherein the inside of each substrate constituting the composite substrate has a separation region which is weak in mechanical strength than the bonded portion, and the composite substrate is separated along the separation region.

According to the above configuration, the bonded substrate including the separation region therein can be separated at a position different from the bonded portion.

The invention described in claim 4 of the application is a method for separating a composite substrate, wherein the separation region is formed by a porous layer formed by an anodizing production method, a fine bubble or crystalline defect layer formed by implantation of ions, or a damage layer.

According to the above configuration, the composite substrate including the separation region therein can be separated at a position different from the bonded portion.

The invention described in claim 5 of the application is a method for separating a composite substrate, wherein the composite substrate has a non-bonded portion of the periphery of each of the plurality of substrates reinforced with an adhesion reinforcer.

According to the above configuration, the periphery of the composite substrate can also be separated along the bonded portion.

The invention described in claim 6 of the application is an apparatus for separating a composite substrate, comprising first housing means for housing a plurality of composite substrates; conveying means for conveying the composite substrates; holding means for holding the composite substrates conveyed by the conveying means; means for warping the composite substrates; and second housing means for housing each substrate, e.g., a substrate such as a silicon substrate, a quartz substrate or the like, which constitutes the composite substrates.

According to the above configuration, a separation apparatus having a simple configuration which can separate each substrate by warping the composite substrate can be provided.

The invention described in claim 7 of the application is an apparatus for separating a composite substrate, further comprising impulse application means which apply an impulse to end surfaces of each substrate constituting the composite substrate while holding the composite substrate in a warped state.

According to the above configuration, there can be provided a separation apparatus which separates the substrate with ease by applying the impulse to start separating even when the separation does not propagate by warping the composite substrate in an elastic deformation region.

### BRIEF DESCRIPTION OF THE DRAWINGS

FIG. 1 is a diagram illustrating a process for separating a composite substrate by a separation apparatus according to a first embodiment of the present invention;

FIG. 2 is a front view of pressure means according to the first embodiment of the invention;

FIG. 3 is a sectional diagram of an impulse application device according to a second embodiment of the invention;

FIG. 4 is a plan view of a separation apparatus according to the second embodiment of the invention;

FIG. 5 is a sectional diagram of a composite substrate according to a third embodiment of the invention; and

FIG. 6 is a sectional diagram of a separated composite substrate according to the third embodiment of the invention.

### DETAILED DESCRIPTION OF THE PREFERRED EMBODIMENTS

The gist of the present invention is to provide a method and an apparatus for separating a composite substrate which separate a silicon substrate from the composite substrate with ease.

Embodiments of the invention will be described in detail with reference to the drawings.

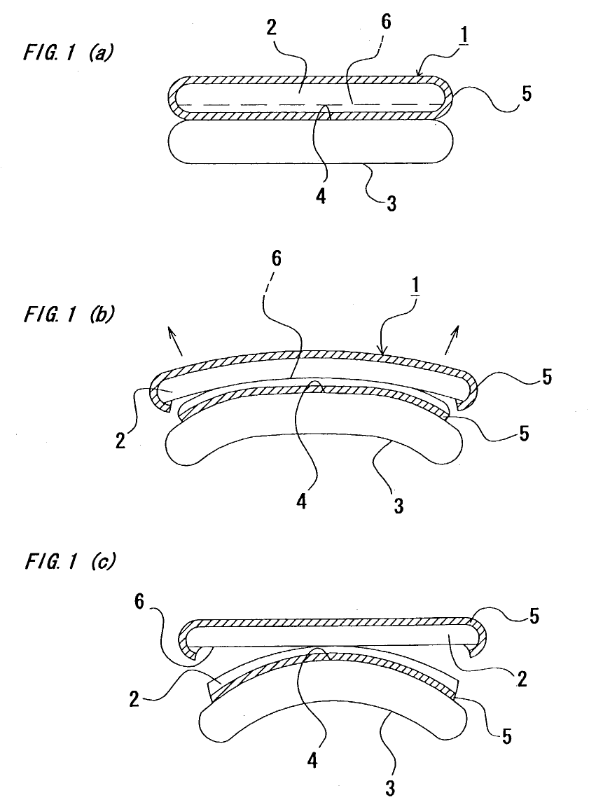

FIG. 1 is a sectional view illustrating a process for separating a composite substrate by the separation apparatus according to a first embodiment of the present invention, wherein a broken line indicates a separation region 6 including fine voids therein.

A composite substrate 1 has silicon substrates 2 and 3 bonded to each other. Reference numeral 4 denotes a bonded surface. The first silicon substrate 2 including the separation region 6 is covered with an oxide film 5, but the second silicon substrate 3 alone or the first and second silicon substrates 2 and 3 may be covered with it. When the composite substrate 1 in the state shown in FIG. 1(a) is warped toward the first silicon substrate 2 to form a convex form as indicated by arrows in FIG. 1(b), a crack is formed in the separation region 6 having a low mechanical strength. Because the periphery of the substrate is not firmly bonded, the crack is produced as shown in FIG. 1(b). When the composite substrate 1 is further warped in a convex form, the crack grows, and the first silicon substrate 2 is mostly separated from the composite substrate 1 as shown in FIG. 1(c). The composite substrate 1 may be warped toward the second silicon substrate 3 to have a convex form.

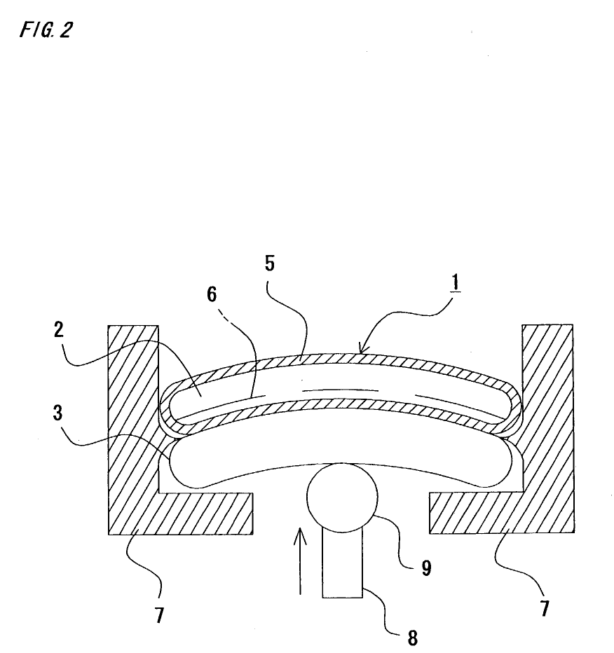

FIG. 2 is a front view of pressure means according to the first embodiment of the present invention, showing that the composite substrate 1 is warped to have a convex form. It is configured that the composite substrate 1 is fixed to a holder 7 by an unillustrated mechanism and a static pressure is applied to approximately the center of the second silicon substrate 3 by a pressure rod 8. The pressure rod 8 is provided with an elastic ball 9 of rubber or the like at a portion for contacting with the composite substrate 1 so a not to damage the second silicon substrate 3 when applying the pressure. When an operator operates to input a signal to an unillustrated control unit, the control unit activates the pressure rod 8, which is then pushed against the second silicon substrate 3. Then, because the composite substrate 1 has only the second silicon substrate 3 fixed to the holder 7, they are separated by virtue of the elastic force of the first silicon substrate 2 as shown in FIG. 1(b) and FIG. 1(c). When the pressure rod 8 is returned to the original position, the first silicon substrate 2 and the composite substrate 1 are separated from each other.

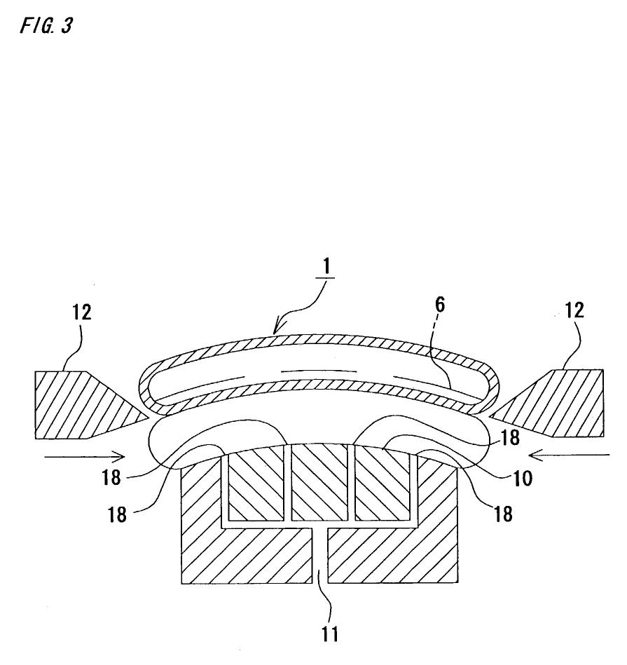

FIG. 3 is a sectional view of a device which warps the composite substrate 1 in a convex form and also applies an impulse to it, according to a second embodiment. As means for warping the composite substrate 1 to have a convex form, the composite substrate 1 is adsorbed to and held by an adsorption table 10 having a curved surface, in the second embodiment. Thus, the composite substrate 1 has a shape along the surface of the adsorption table 10 and warped to have a convex form, but it is not sufficient to make separation, so that it is configured to apply an impulse to edge by impulse application means 12. The adsorption table 10 on which the composite substrate 1 is positioned is provided with vacuum grooves 18, which are connected to unillustrated vacuum suction means (e.g., a vacuum pump) through a pipe 11, and the composite substrate 1 is sucked so that it does not fall from the adsorption table 10. An unillustrated sensor, measuring means and control unit are disposed above the adsorption table 10. And, it is configured that a warped level of the composite substrate 1 is measured, and when the warped level reaches a predetermined level, the impulse application means 12 are moved in directions of arrows shown in the drawing.

An operation of the invention will be described below.

Cracks are produced by applying an impulse to edge by the impulse application means 12, and because the composite substrate 1 has a shape along the surface of the adsorption table 10, the cracks are extended by the elastic force of the first silicon substrate 2, and the composite substrate 1 is separated. The surface of the adsorption table 10 is recommended to be a Teflon chuck or the like fabricated to have a cylindrical or curved surface.

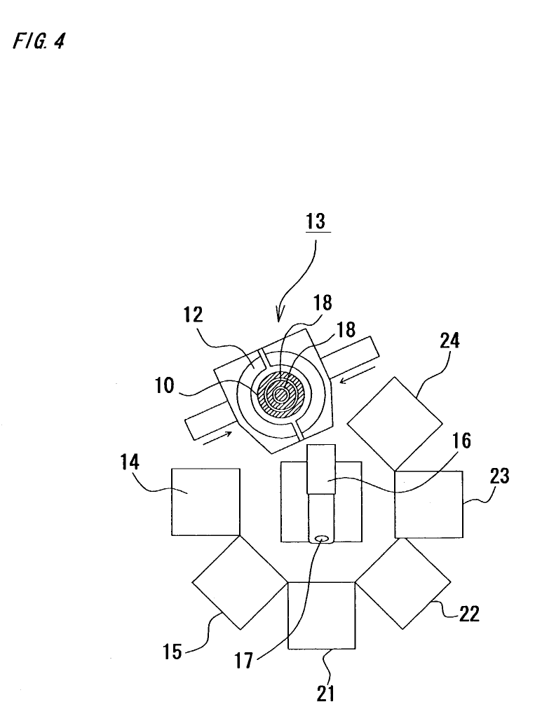

FIG. 4 is a plan view of the separation apparatus of the second embodiment, and a separation step of the composite substrate 1 is performed by a separation station 13. Details of the process for separating the composite substrate 1 by the separation station 13 are omitted because they were already described.

The composite substrate 1 is manually set in a cassette 14 or a cassette 15 which is first housing means. The operator moves a conveying robot 16 and uses an adsorption portion 17 of the conveying robot 16 to remove the composite substrate 1 from the cassette 14 or the cassette 15. And, the composite substrate 1 is positioned on the adsorption table 10 of the separation station 13 and fixed by adsorbing. In this state, force is applied to the composite substrate 1 by the impulse application means 12. Then, the first silicon substrate 2 is separated, an arm of the robot 16 is inversed, and the separated composite substrate 1 is conveyed to cassettes 21 to 24 and housed.

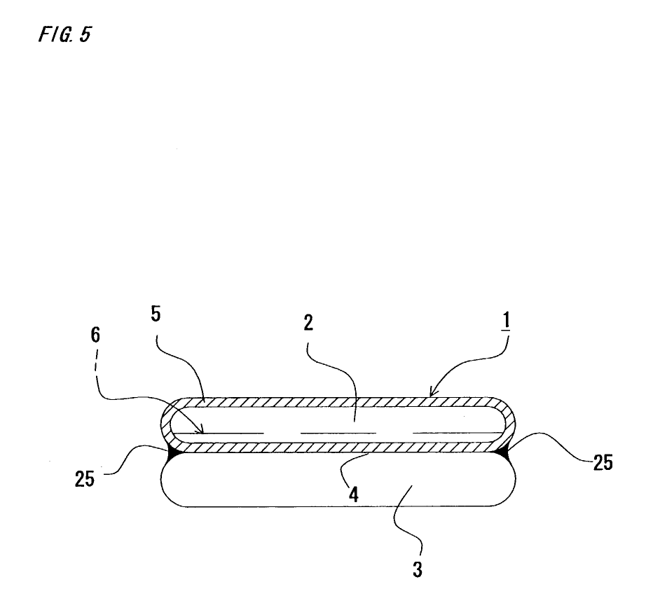

FIG. 5 is a sectional view of the composite substrate 1 used in a third embodiment, showing a non-bonded portion along the periphery of the composite substrate 1, which is bonded with an adhesion reinforcer 25. As the adhesion reinforcer 25, for example an adhesive agent may be used. This configuration can reinforce a bonding strength of the periphery, and the periphery can also be separated along the separation region.

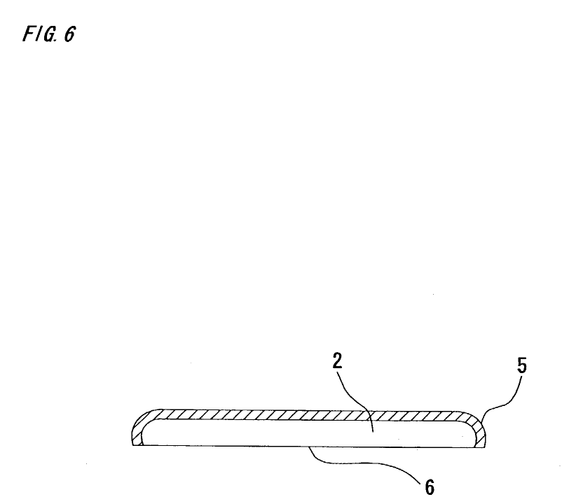

FIG. 6 is a sectional view of the first silicon substrate 2 which was separated by the separation method of the present invention after the adhesion reinforcer 25 was applied to the periphery of the composite substrate 1. In this case, reproduction can be made with ease because no irregularity is formed on the periphery. Although the silicon substrate was used in the embodiments of the invention, it is not limited to silicon substrate, and a quartz substrate, a polysilicon substrate, or the like may also be used.

According to the embodiments described above, the silicon substrate can be separated from the composite substrate with ease.

As described above, according to the separation method and the separation apparatus of the above embodiments, there are advantages that the bonded wafer can be separated at a portion different from the bonded portion with ease, and the separated wafer can be reused as a re-bonded wafer.

What is claimed is:

1. A method for separating a composite substrate which is formed by bonding each of a plurality of substrates, wherein the composite substrate is separated by warping.

2. The method for separating a composite material according to claim 1, wherein an impulse is applied to edge of the composite substrate while keeping it in a warped state.

3. The method for separating a composite substrate according to claim 1 or 2, wherein the inside of each substrate constituting the composite substrate has a separation region which is weak in a mechanical strength than the bonded portion, and the composite substrate is separated along the separation region.

4. The method for separating a composite substrate according to claim 3, wherein the separation region is a porous layer formed by an anodizing production method, a fine bubble or crystalline defect layer formed by implantation of ions, or a damage layer.

5. The method for separating a composite substrate according to claim 3 or 4, wherein the composite substrate has a non-bonded portion of the periphery of each of the plurality of substrates reinforced with an adhesion reinforcer.

6. An apparatus for separating a composite substrate, comprising first housing means for housing a plurality of composite substrates; conveying means for conveying the composite substrates; holding means for holding the composite substrates conveyed by the conveying means; means for warping the composite substrates; and second housing means for housing each substrate which constitutes the composite substrates.

7. The apparatus for separating a composite substrate according to claim 6, further comprising impulse application means which apply an impulse to end surfaces of each substrate constituting the composite substrate while holding the composite substrate in a warped state.
